(19) United States
(12) Patent Application Publication
(10) Pub. No.: US 2025/0309111 A1
(43) Pub. Date: Oct. 2, 2025

(54) DIRECT BACKSIDE CONTACTS FOR STACKED TRANSISTOR ARCHITECTURES

(71) Applicant: International Business Machines Corporation, Armonk, NY (US)

(72) Inventors: Nicholas Anthony Lanzillo, Wynantskill, NY (US); Reinaldo Vega, Mahopac, NY (US); Ruilong Xie, Niskayuna, NY (US); Lawrence Alfred Clevenger, Saratoga Springs, NY (US); Albert M. Chu, Nashua, NH (US); Brent A. Anderson, Jericho, VT (US)

(21) Appl. No.: 18/622,887

(22) Filed: Mar. 30, 2024

(51) Int. Cl. H01L 23/528; H01L 21/768; H01L 27/092

(52) U.S. Cl. CPC H01L 23/5283; H01L 21/76898; H10D 84/856

(57) ABSTRACT

An exemplary semiconductor structure includes a bottom source drain, a top source drain located above the bottom source drain, where the top source drain has a backside, a two-stage backside contact having an upper portion and a lower portion, and a backside first metal line in which the upper portion contacts the backside of the top source drain and the lower portion contacts the backside first metal line.

### BACKGROUND

The present invention relates generally to the electrical, electronic and computer arts and, more particularly, to techniques for incorporating backside contacts to stacked field effect transistor (FETs) configurations and the like.

Complementary Metal-oxide-semiconductor (CMOS) technology is commonly used for field effect transistors (hereinafter “FET”) as part of advanced integrated circuits (hereinafter “IC”), such as central processing units (hereinafter “CPUs”), memory, storage devices, and the like. As demands to reduce the dimensions of transistor devices continue, stacked FETs help achieve a reduced FET device footprint while maintaining FET device performance. A stacked FET device contains at least one transistor at least partially stacking over at least another transistor.

Buried power rails (BPR) and backside power distribution networks (BSPDN) are very attractive schemes for future complementary metal oxide semiconductor (CMOS) scaling. Backside contacts are used to connect FETs to the BPR and BSPDN.

However, with continued scaling, a problem has arisen regarding incorporating effective contacts.

FIG. 1A is a top view of aspects of a prior art integrated circuit structure. Semiconductor first active area 101 and a second active area 102 are spaced apart from each other and are both orthogonal to one or more gates 105.

FIG. 1B is a cross-gate view of the device of FIG. 1A along line Y in FIG. 1A showing a backside direct contact (DBC) 130 in contact and between the first active area 101 and backside first metal line 140. Spacers 110 may border the first active area and second active area 102. The active area can be further divided into a channel region under the gate 105 and remainder being source/drain regions. Thus, the FIG. 1B cross-section captures the source/drain regions of the active areas. Also depicted in FIG. 1B are various interlevel dielectric (ILD) layers, including frontside ILD 120, and first backside ILD 160. The frontside ILD 120 overlays the top and sides of the active areas and spacers. The first backside ILD 160 laterally surrounds and is co-planar with backside first metal line 140.

### BRIEF SUMMARY

Principles of the invention provide techniques for incorporating backside contacts to stacked and non-stacked field effect transistor (FETs) configurations and the like. In one aspect, an exemplary semiconductor structure includes a first source drain having a frontside and a backside, a two-stage backside contact having an upper portion and a lower portion, and a backside first metal line, in which the upper portion contacts the backside of the first source drain and the lower portion contacts the backside first metal line.

In another aspect, another exemplary semiconductor structure includes a bottom source drain, a top source drain located above the bottom source drain wherein the top source drain has a backside, a two-stage backside contact having an upper portion and a lower portion, and a backside first metal line in which the upper portion contacts the backside of the top source drain and the lower portion contacts the backside first metal line.

In still a further aspect, an exemplary method of forming a semiconductor structure includes providing a substrate having a frontside and a backside, forming a stacked field effect transistor structure having at least one bottom source drain region and at least one top source drain region and a frontside interlevel dielectric on the frontside, thinning the backside, forming a backside dielectric layer, forming a single-stage direct backside contact in the backside dielectric layer to the at least one bottom source drain region, forming a two-stage direct backside contact in the backside dielectric layer and the frontside interlevel dielectric to the at least one top source drain region on the frontside, and forming a backside first metal line in contact with the two-stage direct backside contact.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1A is a top view of aspects of a prior art semiconductor structure;

FIG. 1B is a cross-sectional view of the device of FIG. 1 along line Y in FIG. 1 showing a direct backside contact (DBC) in contact and between the first active area and backside first metal line (BM1);

FIGS. 2A-2D depict a semiconductor structure having various a two-stage direct backside contact in accordance with aspects of the invention;

FIG. 3 depicts a top-down view of a stacked FET configuration of a semiconductor structure according in accordance with aspects of the invention; and

FIGS. 4-9 are cross-sectional views of the semiconductor structure of FIG. 3 along line Y in FIG. 3 showing a two-stage direct backside contact (DBC) of a stacked FET configuration according in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure includes a first source drain 201 having a frontside and a backside, a two-stage direct backside contact (two-stage DBC 230) having an upper portion 231 and a lower portion 232, and a backside first metal line 140, in which the upper portion 231 contacts the backside of the first source drain 201 and the lower portion contacts the backside first metal line 140. A technical benefit is tailoring of backside contact resistance by selection of upper and lower portion dimensions. More specifically, in some embodiments, the upper portion can be made to have a smaller height than the lower portion, minimizing the series resistance of the two segments.

Optionally, the upper portion 231 has a largest width which is less than the lower portion's 232 largest width. A technical benefit is tailoring of backside contact resistance by selection of upper and lower portion dimensions. Proper dimension selection can also impact scaling of designs and manufacturability. For example, designers can design a larger lower section and not have to worry about shorting to nearby devices since the upper segment is smaller.

Optionally, the upper portion 231 has a largest width which is less than the lower portion's 232 smallest width. A technical benefit is tailoring of backside contact resistance by selection of upper and lower portion dimensions to minimize series resistance of the two portions. Proper dimension selection can also impact scaling of designs and manufacturability.

Optionally, the upper portion 231 has a height which is less than a lower portion height. A technical benefit is tailoring of backside contact resistance by selection of upper and lower portion dimensions. Here, series resistance is optimized but by tuning the height instead of the width. Ideally, the height of the upper portion (which is the resistance bottleneck) would be made as short as possible so that the lower-resistance lower portion occupies more space. Proper dimension selection can also impact scaling of designs and manufacturability.

Optionally, the upper portion 231 contacts the backside of a second source drain 202. Technical benefits are design flexibility since two devices can be contacted with only a single conductor and reduced resistance of the upper portion.

Optionally, the semiconductor structure further includes a second upper portion 231 and a second source drain 202 in which the second upper portion 231 contacts the backside of the second source drain 202 and contacts the lower portion 232. A technical benefit is design flexibility. For example, instead of using two tall/narrow single-segment connections, both devices can benefit from having a wider bottom segment with lower resistance.

Optionally, the upper portion 231 is laterally centered with respect to the lower portion 232. A technical benefit is improved manufacturability as use of a single mask is enabled. Specifically, when there is lateral alignment, a single mask, instead of two masks, can be used along with different etch chemistries to achieve different widths. Thus, cost savings are achieved by eliminating one mask.

Optionally, the upper portion 231 is not laterally centered with respect to the lower portion 232. A technical benefit is design flexibility.

Optionally, the upper portion 231 and the lower portion comprise the same material. A technical benefit is manufacturing efficiency.

In a further aspect, an exemplary semiconductor structure includes a bottom source drain 301, a top source drain 303 located above the bottom source drain wherein the top source drain has a backside, a two-stage DBC 230 having an upper portion 231 and a lower portion 232 and a backside first metal line 140 in which the upper portion 231 contacts the backside of the top source drain 303 and the lower portion 321 contacts the backside first metal line 140. A technical benefit is enabling the manufacturing of low resistance backside contacts to stacked FETs.

Optionally, the upper portion 231 has a largest width which is less than a lower portion largest width. A technical benefit is tailoring of backside contact resistance by selection of upper and lower portion dimensions. Proper dimension selection can also impact scaling of designs and manufacturability.

Optionally, the upper portion has a largest width which is less than a lower portion smallest width. A technical benefit is tailoring of backside contact resistance by selection of upper and lower portion dimensions. Proper dimension selection can also impact scaling of designs and manufacturability.

Optionally, the upper portion 231 has a height which is less than a lower portion height. A technical benefit is tailoring of backside contact resistance by selection of upper and lower portion dimensions. Proper dimension selection can also impact scaling of designs and manufacturability.

Optionally, the upper portion 231 contacts the backside of a second top source drain 304. A technical benefit is design flexibility and reduced resistance of the upper portion.

Optionally, the semiconductor structure further includes a second upper portion 231, a second top source drain 304, in which the second upper portion 231 contacts the backside of the second top source drain 304 and contacts the lower portion 232. A technical benefit is design flexibility.

Optionally, the upper portion 231 is laterally centered with respect to the lower portion 232. A technical benefit is improved manufacturability as use of a single mask is enabled.

Optionally, the upper portion 231 is not laterally centered with respect to the lower portion 232. A technical benefit is design flexibility.

Optionally, the semiconductor structure further includes a frontside interlevel dielectric (frontside ILD 120) and a backside dielectric layer 270, and in which the lower portion 232 is partially in the frontside ILD (120) and partially in the backside dielectric layer 270. A technical benefit is enablement of a lower resistance backside contact to a stacked FET. In addition, this approach allows a lower-k dielectric to be used as the backside dielectric layer 270, which reduces the capacitance of the backside interconnects (e.g. backside first metal line 140). This also allowed for process optimization, as frontside ILD 120 can be tailored for optimized front end of line processing while dielectric backside dielectric layer 270 can be tailored for easy etching of the backside contacts.

Optionally, the semiconductor structure further includes a frontside ILD 120 in which the upper portion 231 is in the frontside interlevel dielectric 120. Similar to above, a technical benefit is resistance/capacitance tailoring with selection of dielectric layer materials at various locations.

In still a further aspect, an exemplary method of forming a semiconductor structure includes providing a substrate having a frontside and a backside, forming a stacked field effect transistor structure having at least one bottom source drain region and at least one top source drain region and a frontside interlevel dielectric on the frontside, thinning the backside, forming a backside dielectric layer, forming a single-stage direct backside contact in the backside dielectric layer to the at least one bottom source drain region, forming a two-stage direct backside contact in the backside dielectric layer and the frontside interlevel dielectric to the at least one top source drain region on the frontside, and forming a backside first metal line in contact with the two-stage direct backside contact. The technical benefit is enabling the manufacturing of low resistance backside contacts to stacked FETs.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:

Enabling lower resistance direct backside contacts which is particularly useful in stacked FETs by:
providing a second, larger contact section which lowers resistance, and/or
reducing the heigh of the first, narrow contact section.

Enabling design flexibility by allowing backside contact either to a single device or two adjacent devices.

Enhancing manufacturability of backside contacts to top devices of stacked FETs.

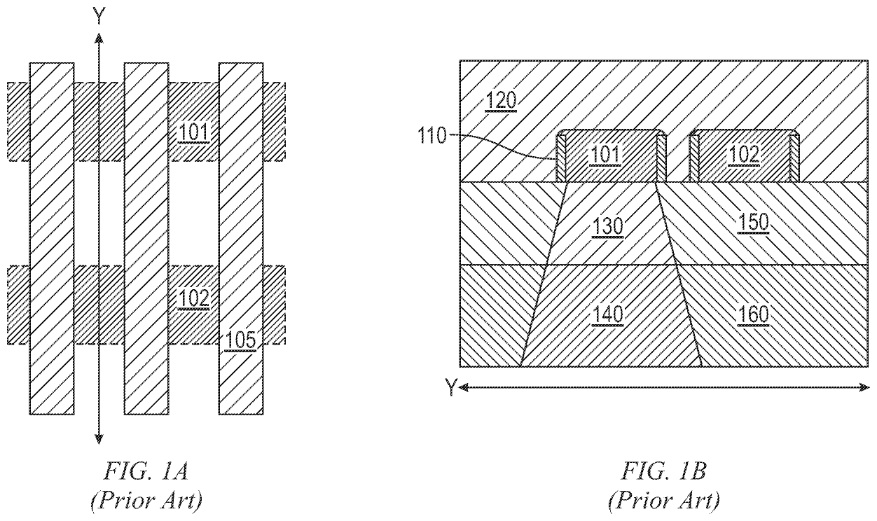

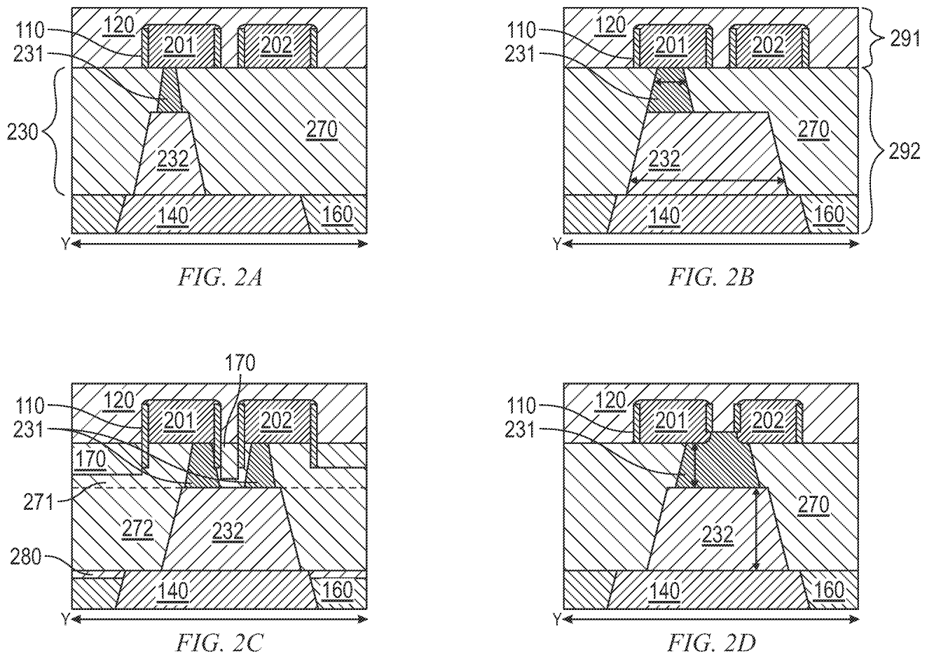

Aspects of invention provide techniques for incorporating backside contacts to various FET configurations. Referring now to FIGS. 2A-2D are variations of a two-stage backside contact in accordance with aspects of the invention. Referring to FIG. 2A, the prior art's backside direct contact (DBC) 130 of FIG. 1B is replaced by a two-stage direct backside contact (two-stage DBC) 230 having an upper portion 231 and a lower portion 232. The upper portion 231 contacts the backside of a first source drain 201 of an active area and the lower portion 232 contacts the backside first metal line 140. The two-stage DBC 230 can be embedded in a backside dielectric layer 270. As explained in more detail in FIG. 2C, the backside dielectric layer 270 can be a single layer or include multiple dielectric materials or layers.

In FIG. 2A, the upper portion 231 and the lower portion 232 appear to be two single damascene contact structures, the invention also contemplates that the upper portion 231 and the lower portion 232 are a dual damascene contact structure. The upper portion 231 and the lower portion 232 can be made of different conducting materials or the same materials. By way of example, one stage of the two-stage DBC 230 can be tungsten while the other is cobalt, or both stages can be tungsten or cobalt. The materials and structure (single damascene or dual damascene) described in conjunction with FIG. 2A applies to all non-prior art figures. The choice of single versus dual damascene could be driven by metallization or by overlay/patterning requirements. If the overlay margin is very tight, single damascene may be preferred. In addition, if different metals are desired for the upper/lower segments, single damascene can be used to achieve this. Otherwise, dual damascene will fill both upper and lower segments with the same metal during the same processing step.

Continuing with FIG. 2A, the two-stage DBC 230 connects to one device (i.e. one source drain 201 of an active area). Also note that the upper portion 231 and lower portion 232 are centered (within process tolerances) with respect to each other, this symmetric staging allows the two-stage DBC 230 to be created using a single mask. As long as the upper and lower segments are laterally aligned, the same mask can be used but with two different etch chemistries. The different etch chemistries will give the different widths/heights for the upper/lower segments.

In contrast to FIG. 2A, FIG. 2B depicts an aspect of the two-stage DBC 230 requiring two masks. While FIG. 2B still connects to one device (i.e. one source drain 201 of an active area), the upper portion 231 and lower portion 232 are not centered (within process tolerances) with respect to each other, this asymmetric staging requires the two-stage DBC (230) be created using two masks. While the additional mask layer has cost and time disadvantages, in some cases it is desirable due to the wider contacts it enables which further lowers the resistance of the structure.

Continuing with FIG. 2B, the horizontal double-headed arrows within the upper portion 231 and the lower portion 232 indicate the direction the width of the upper portion 231 and the lower portion 232 is measured. The upper portion 231 has a largest width which is less than a lower portion 232 largest width. The upper portion 231 has a largest width which is less than a lower portion 232 smallest width. The relative widths of the upper portion 231 and lower portion 232 described in conjunction with FIG. 2B applies to all non-prior art figures.

FIG. 2B also illustrates the frontside 291 and the backside 292 of the semiconductor structure. Here, features above the bottom of the first source drain 201 or second source drain 202 are on the frontside 291 and features below are on the backside 292. The frontside 291 features include source drains, frontside ILD 120, and frontside contacts (not shown) which connect the front (top) of the source drains to the back end of line (also not shown). Frontside ILD 120 can be one of more layers, liners or plugs or combinations of the same made from the same or different dielectric materials. The backside 292 includes backside dielectric layer 270 (further explained in conjunction with FIG. 2C), all or part of the two-stage DBC 230 depending upon the aspect of the invention, and the backside first metal line 140 and accompanying first backside ILD 160.

In contrast to FIGS. 2A-2B, FIG. 2C depicts an aspect of the two-stage DBC 230 which is in contact with two devices, namely a first source drain 201 and a second source drain 202 of different active areas. Here, the two-stage DBC 230 includes two upper portions 231, one to each source drain, in which each land on a common lower portion 232. Also, in FIG. 2C, more detail is given regarding backside insulating layer variations applicable to all non-prior art figures. Previously, it was mentioned that backside dielectric layer 270 could include one or more other insulating layers. FIG. 2C illustrates some non-limiting examples of other insulating layers that can be used any combination. First, in FIG. 2C, backside dielectric layer 270 can have two layers, namely an upper backside dielectric layer 271 and a lower backside dielectric layer 272. In general, the upper backside dielectric layer 271 can encompass the upper portion 231 of the DBC while the lower backside dielectric layer 272 can encompass the lower portion 232 of the DBC. In FIG. 2C an optional etch stop layer 280 is between the lower backside dielectric layer 272 and the first backside ILD 160. While not pictured an etch stop layer can optionally be between the upper backside dielectric layer 271 and lower backside dielectric layer 272. As with all FIGS. 2A-2D the upper portion 231 of the two-stage DBC is directly under the first source drain 201 and/or the second source drain 202 while trench isolation 170 regions can be on either side of source drains. The various insulating/dielectric layers can be silicon oxides, nitrides, carbides or mixtures of the same. The etch stop layer 280 usually contains nitrogen but need not as long as it can be etch more slowly than the adjacent layer being etched (e.g. first backside ILD 160 in the FIG. 2C example).

Turning to FIG. 2D, like the prior figure, two devices (a first source drain 201 and a second source drain 202 of different active areas) are contacted, but this time by a single upper portion 231 of the two-stage DBC which is connected, in turn, to a lower portion 232. In some instances (as illustrated in FIG. 2D), the upper portions 231 may extend into the frontside ILD 120 and up a sidewall of one or more of the source drains. By wrapping around and contacting both the bottom and sidewall of the source drain, the contact resistance is reduced. It should be noted that this “wrap-around” version of the upper portion 231 of the two-stage DBC 230 is also applicable to FIGS. 2A-2C and 4-9. The vertical double-headed arrows within the upper portion 231 and the lower portion 232 indicate the direction the height of the upper portion 231 and the lower portion 232 is measured. Note, for the purposes of upper portion 231 height measurements, the height is measured from the bottom of the source drain 201 or 202 to the lower portion 232, even in the case of a wrap-around upper portion 231. In the FIG. 2A-2D examples, the upper portion 231 has a height which is less than a height of a lower portion 232, though it is not a requirement. As described in conjunction with FIG. 2A, the upper portion 231 is centered with respect to the lower portion 232 enabling the use of a single mask to create the two-stage DBC 230.

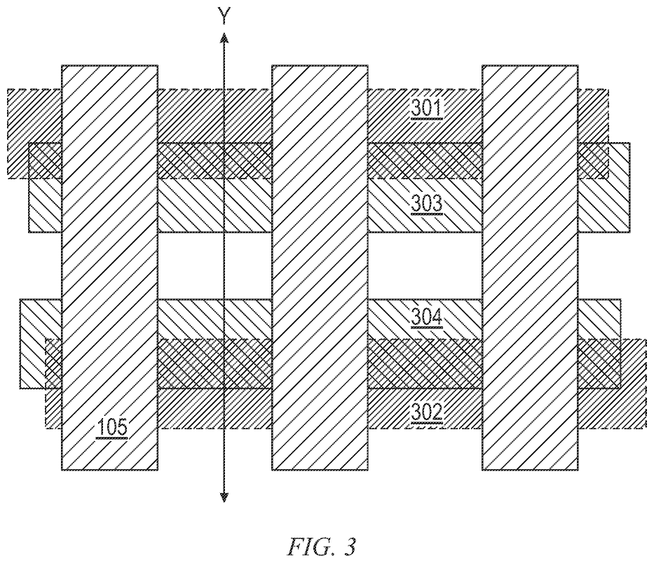

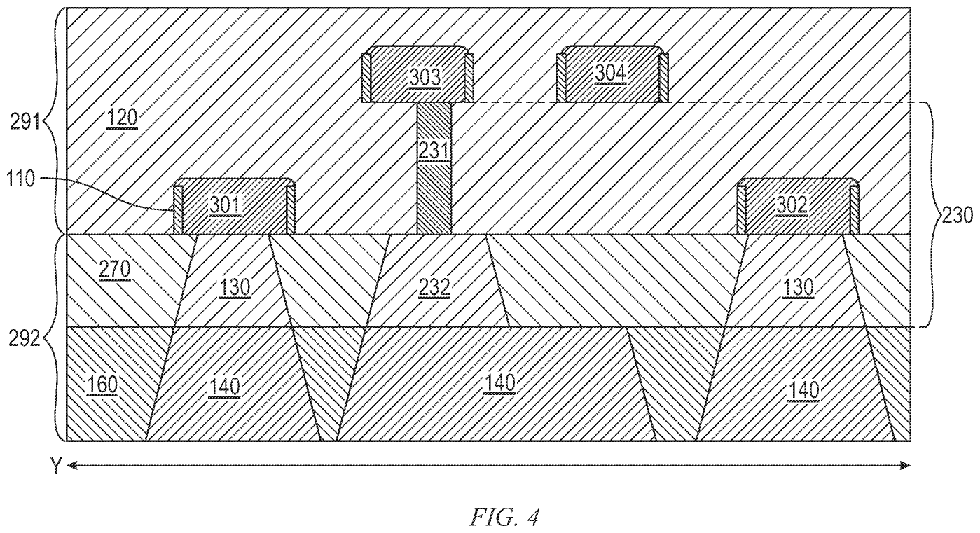

FIG. 3 depicts a top-down view of a stacked FET according to an aspect of the invention. Here there are bottom source drain 301/302 regions on two different active areas located at the substrate-level and top source drain 303/304 regions on two different active areas located above the substrate-level. Both top and bottom active areas are crossed by one or more gates 105. The bottom source drain 301/302 regions can both be of one polarity FET (e.g. NFET) while the top source drain 303/304 regions can both be of the opposite polarity (e.g. PFET). The vertical double-headed arrow of FIG. 3 indicates the cross-section location of aspects of the invention depicted in FIGS. 4-9.

FIG. 4 depicts a cross-section of FIG. 3 taken along the Y-direction of FIG. 3. FIG. 4 depicts single stage DBCs 130 to bottom source drain 301/302 regions while one of the top source drain 303/304 regions of the stacked FET are contacted by a two-stage DBC 230 having an upper portion 231 and a lower portion 232. In FIG. 4, the lower portion 232 of the two-stage DBC 230 is at the same level as the single-stage DBC 130 and is embedded in backside dielectric layer 270. Thus, the lower portion 232 is at a level which is vertically lower than the bottom source drain 301/302 regions. In contrast, in the FIG. 4 example, the upper portion 231 of the two-stage DBC 230 is in the frontside of the device and embedded in frontside ILD 120 as it makes its way from the lower portion 232 to one of the top source drain 303/304 regions. Similar to FIG. 2D, FIG. 4 two-stage DBC 230 depicted is symmetric; An asymmetric configuration is also possible. In FIG. 4, the height of the upper portion 231 of the two-stage DBC 230 is greater than the height of the lower portion 232. The upper portion 231 and the lower portion 232 can be a dual damascene structure or each a single damascene structure.

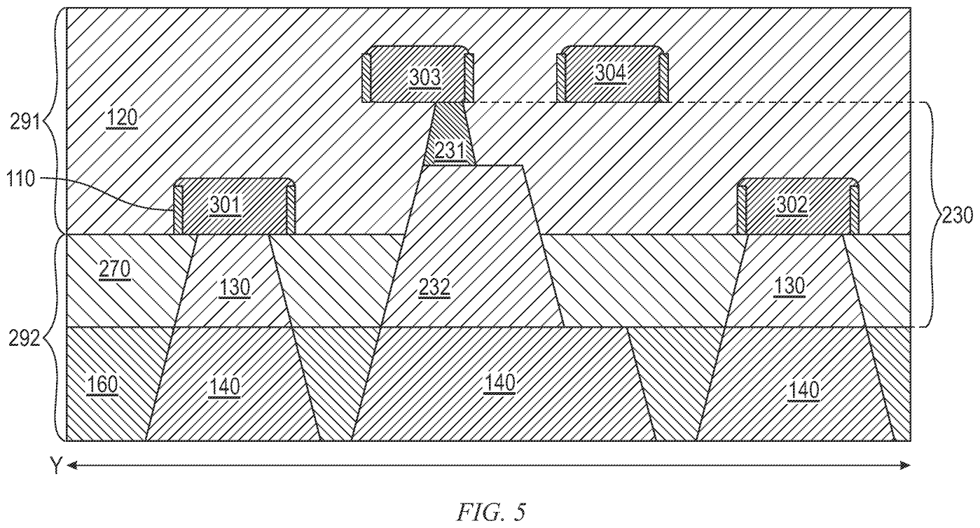

Like FIG. 4, FIG. 5 depicts a cross-section of FIG. 3 taken along the Y-direction of FIG. 3 in which single stage DBCs 130 contact bottom source drain 301/302 regions while one of the top source drain 303/304 regions of the stacked FET are contacted by a two-stage DBC 230 having an upper portion 231 and a lower portion 232. However, in FIG. 5, the lower portion 232 of the two-stage DBC 230 has one side (lower) coplanar with a side (lower) of the single-stage DBC 130 embedded in backside dielectric layer 270. Unlike the single-stage DBC 130, the lower portion 232 of the two-stage DBC 230 also extends upward into the frontside ILD 120. The upper portion 231 of the two-stage DBC 230 is in the frontside of the device and embedded in frontside ILD 120 as it makes its way from the lower portion 232 to one of the top source drain 303/304 regions. Similar to FIG. 2B, FIG. 5's two-stage DBC 230 is asymmetric; a symmetric configuration is also possible. In FIG. 5, the height of the upper portion 231 of the two-stage DBC 230 can be less or equal to the height of the lower portion 232, though it is not a requirement. The upper portion 231 and the lower portion 232 can be a dual damascene structure or each a single damascene structure.

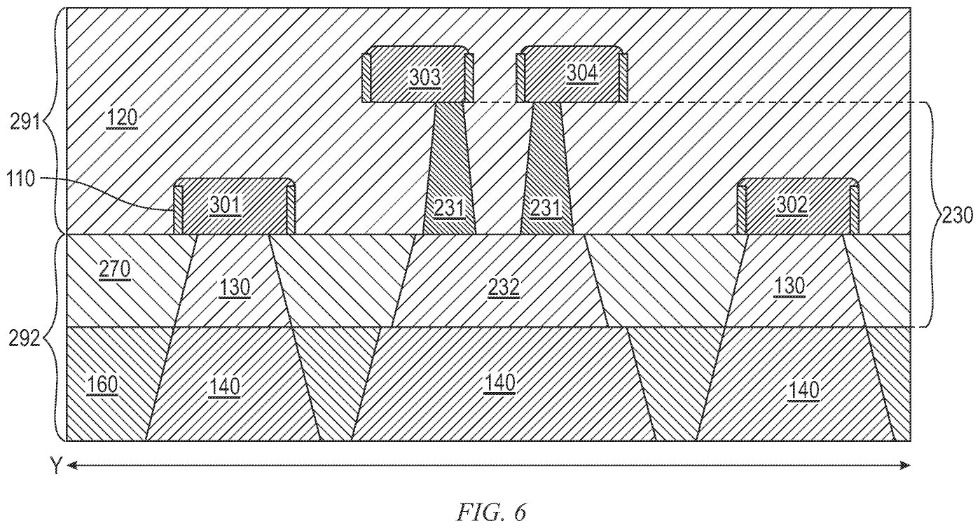

Turning to FIG. 6 which shares the same features as described in FIG. 4 but also includes a second upper portion 231 of the DBC 230 contacting a second device (e.g. source drain 304 of second active area). The second upper portion 231 of the DBC 230 also contacts the common lower portion 232 of the two-stage DBC 230.

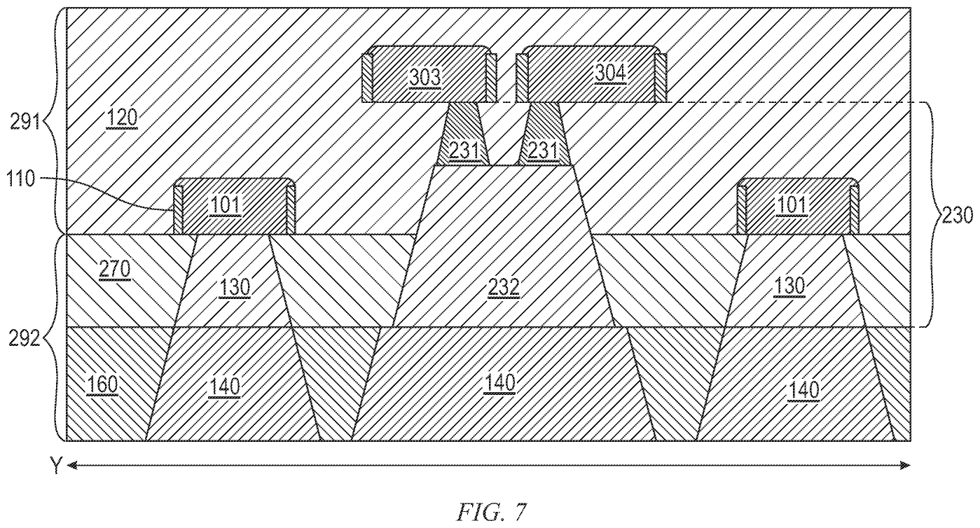

Turning to FIG. 7 which shares the same features as described in FIG. 5 but also includes a second upper portion 231 of the two-stage DBC 230 contacting a second device (e.g. source drain 304 of second active area). The second upper portion 231 of the DBC 230 also contacts the common lower portion 232 of the two-stage DBC 230.

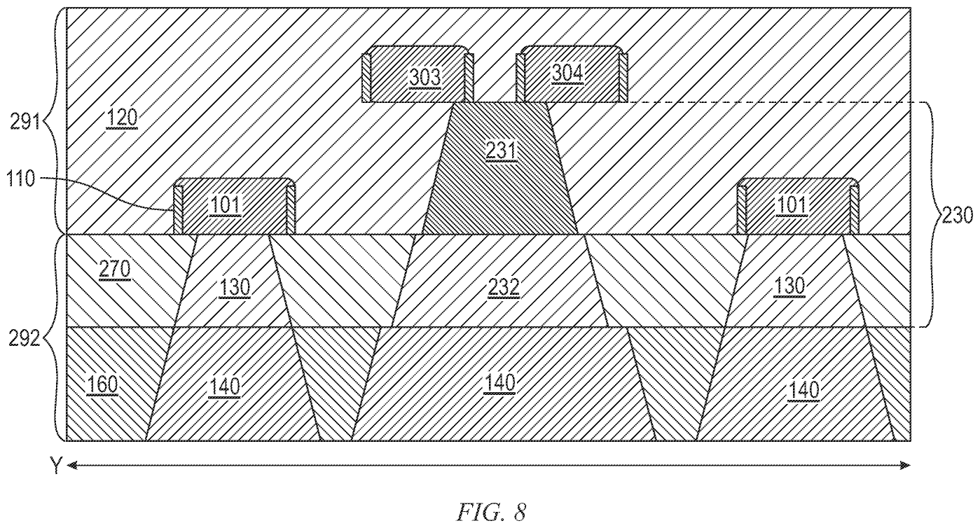

Turning to FIG. 8 which shares the same features as described in FIG. 4 except for the upper portion 231 of the two-stage DBC 230 also contacting a second device (e.g. source drain 304 of second active area) such that the two-stage DBC 230 contacts two devices instead of one.

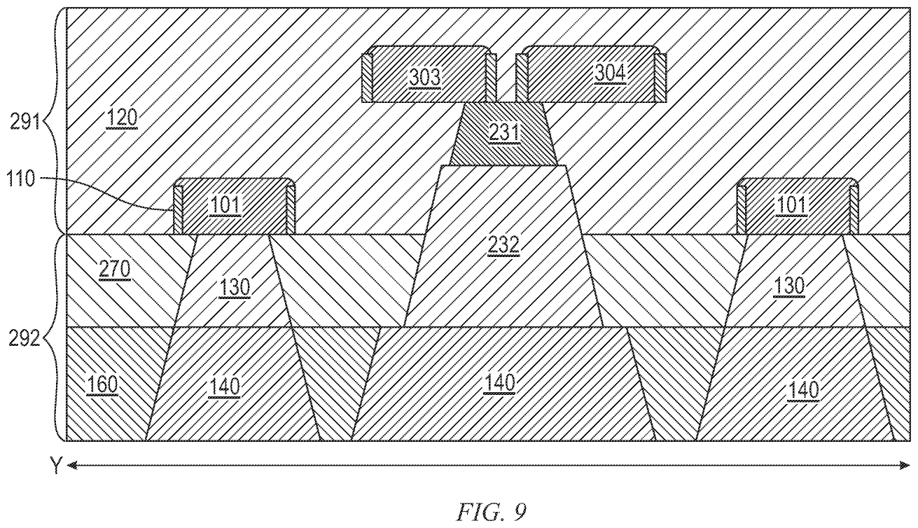

Turning to FIG. 9 which shares the same features as described in FIG. 5 except for the upper portion 231 of the two-stage DBC 230 also contacting a second device (e.g. source drain 304 of second active area) such that the two-stage DBC 230 contacts two devices instead of one.

Silicon, doped silicon and silicon germanium are a non-limiting example of a suitable semiconductor material, other materials are also possible. Active areas, including channel and source drain regions include semiconductor material.

As used herein, a line refers to a conductive structure having a longest length (viewed top down) greater than its width and greater than its height (viewed in cross-section). A line can connect one via to another via, one contact to another contact (then, often referred to as a local interconnect), or one contact to a via. A via, as used herein, is a conductive structure in which is normally circular or oval when viewed top-down. In the case of an oval via, the height or width (viewed in cross-section) of the via is greater than or equal to its length (viewed top-down). A via connects an underlying line to an overlying line, or a via can connect an underlying contact to an overlying line or via. A contact, as used herein, is similar to a via in shape but connects a transistor element (i.e. source, drain or gate) to a via or a line.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a first source drain having a frontside and a backside;
a two-stage backside contact having an upper portion and a lower portion; and
a backside first metal line;
wherein the upper portion contacts the backside of the first source drain and the lower portion contacts the backside first metal line.

2. The semiconductor structure of claim 1, wherein the upper portion has a largest width which is less than a lower portion largest width.

3. The semiconductor structure of claim 1, wherein the upper portion has a largest width which is less than a lower portion smallest width.

4. The semiconductor structure of claim 1, wherein the upper portion has a height which is less than a lower portion height.

5. The semiconductor structure of claim 1, further comprising a second source drain having a backside, wherein the upper portion contacts the backside of the second source drain.

6. The semiconductor structure of claim 1, further comprising:
a second upper portion; and
a second source drain;
wherein the second upper portion contacts the backside of the second source drain and contacts the lower portion.

7. The semiconductor structure of claim 1, wherein the upper portion is laterally centered with respect to the lower portion.

8. The semiconductor structure of claim 1, wherein the upper portion is not laterally centered with respect to the lower portion.

9. The semiconductor structure of claim 1, wherein the upper portion and the lower portion are composed of a same material.

10. A semiconductor structure comprising:
a bottom source drain;
a top source drain located above the bottom source drain, wherein the top source drain has a backside;
a two-stage backside contact having an upper portion and a lower portion; and
a backside first metal line;
wherein the upper portion contacts the backside of the top source drain and the lower portion contacts the backside first metal line.

11. The semiconductor structure of claim 10, wherein the upper portion has a largest width which is less than a lower portion largest width.

12. The semiconductor structure of claim 10 wherein the upper portion has a largest width which is less than a lower portion smallest width.

13. The semiconductor structure of claim 10, wherein the upper portion has a height which is less than a lower portion height.

14. The semiconductor structure of claim 10, further comprising a second top source drain having a backside, wherein the upper portion contacts the backside of the second top source drain.

15. The semiconductor structure of claim 10, further comprising:
a second upper portion; and
a second top source drain having a backside;
wherein the second upper portion contacts the backside of the second top source drain and contacts the lower portion.

16. The semiconductor structure of claim 10, wherein the upper portion is laterally centered with respect to the lower portion.

17. The semiconductor structure of claim 10, wherein the upper portion is not laterally centered with respect to the lower portion.

18. The semiconductor structure of claim 10, further comprising:
a frontside interlevel dielectric; and
a backside dielectric layer;
wherein the lower portion is partially in the frontside interlevel dielectric and partially in the backside dielectric layer.

19. The semiconductor structure of claim 10, further comprising a frontside interlevel dielectric, wherein the upper portion is in the frontside interlevel dielectric.

20. A method of forming a semiconductor structure, comprising:
providing a substrate having a frontside and a backside;
forming a stacked field effect transistor structure having at least one bottom source drain region and at least one top source drain region and a frontside interlevel dielectric on the frontside;
thinning the backside;
forming a backside dielectric layer;
forming a single-stage direct backside contact in the backside dielectric layer to the at least one bottom source drain region;
forming a two-stage direct backside contact in the backside dielectric layer and the frontside interlevel dielectric to the at least one top source drain region on the frontside; and
forming a backside first metal line in contact with the two-stage direct backside contact.
